(19) United States
(12) Patent Application Publication
(10) Pub. No.: US 2006/0091927 A1
(43) Pub. Date: May 4, 2006

(54) Delay stage for a digital delay line

(76) Inventor: Huawen Jin, Plano, TX (US)

Correspondence Address: TEXAS INSTRUMENTS INCORPORATED, P O BOX 655474, M/S 3999, DALLAS, TX, 75265, US

(21) Appl. No.: 10/983,045

(22) Filed: Nov. 3, 2004

(51) Int. Cl. H03H 11/26

(52) U.S. Cl. 327/284

(57) ABSTRACT

A delay stage for a digital delay line comprising: a first string of delay segments coupled in series; a second string of delay segments coupled in series; pass gates coupled between the first string of delay segments and the second string of delay segments, wherein each delay segment in the first string of delay segments has an output coupled to an input of a corresponding one of the pass gates, and a corresponding delay segment in the second string of delay segments has an input coupled to an output of the corresponding one of the pass gates. The number of delay elements that make up the delay line is determined by selecting one of the pass gates.

### FIELD OF THE INVENTION

The present invention relates to electronic circuitry and, in particular, to a delay stage for a digital delay line.

### BACKGROUND OF THE INVENTION

An example digital delay device is shown in FIG. 1. The device of FIG. 1 includes delay elements 20, element select multiplexer (MUX) 22; input in; and output out. The total delay amount is determined by how many delay elements are chosen. The more elements chosen, the longer the delay amount from port ‘in’ to port ‘out’ at a given technology and voltage/temperature (VT) corner. Generally, the delay element is made from standard digital library cells. The minimum delay amount will be one delay element.

In order to select which element to be the output, several methods can be used. The straightforward thinking would be to use a big MUX. However, as the number of delay elements increases well into the hundreds, the MUX will become quite complicated and have additional delay.

Shown in FIG. 2 is one prior art solution to eliminate the design of a big MUX. The device of FIG. 2 is a parallel driving scheme. The input clock phase needs to arrive at each delay element at the same time. This can be done by using two levels of hierarchy to simplify the logic. The input clock first reaches input nodes IN0, IN1, IN2, and IN3 at the same time. Then, each delay element receives input clock phase at the same time. To do this, extra delay is introduced by two level (or multi-level) clock distribution logic as a fixed offset in time.

In this scheme, delay elements will work in three situations. First is to act as ‘pass’ gate, which simply adds a certain amount of delay to its input. Second is to act as ‘dead’ gate, which will not output anything but a constant level. Third is to act as ‘inject’ gate, which allows the gate to accept input clock and output a delayed version.

Hence, the question of selecting how many elements to be used becomes the question of where to place the ‘inject’ gate. Since every delay element is identical, connections and top-level logic are greatly simplified. There is one assumption that all elements can see the same phase so that no matter where the ‘inject’ gate is, the real delay is not influenced by the location.

However, this method suffers one big problem of how to put in the reference clock. Since the number of delay elements is large, the requirement that each element sees identical input is not easy to achieve. From FIG. 2, a clock is re-driven to become multiple inputs. There will be phase errors in between different ones, which leads to different phase relationships while choosing different elements to be the ‘inject’ gate.

### SUMMARY OF THE INVENTION

The delay stage for a digital delay line includes: a first string of delay segments coupled in series; a second string of delay segments coupled in series; pass gates coupled between the first string of delay segments and the second string of delay segments, wherein each delay segment in the first string of delay segments has an output coupled to an input of a corresponding one of the pass gates, and a corresponding delay segment in the second string of delay segments has an input coupled to an output of the corresponding one of the pass gates. The number of delay elements that make up the delay line is determined by selecting one of the pass gates.

### BRIEF DESCRIPTION OF THE DRAWINGS

In the drawings:

FIG. 1 is a diagram of a digital delay device;

FIG. 2 is a diagram of a prior art parallel driving scheme for a digital delay device;

FIG. 3. is a diagram of a serial driving scheme for a digital delay stage, according to the present invention;

FIG. 4. is a diagram of a delay element for the device of FIG. 3, according to the present invention;

FIG. 5. is a truth table for the delay element of FIG. 4.

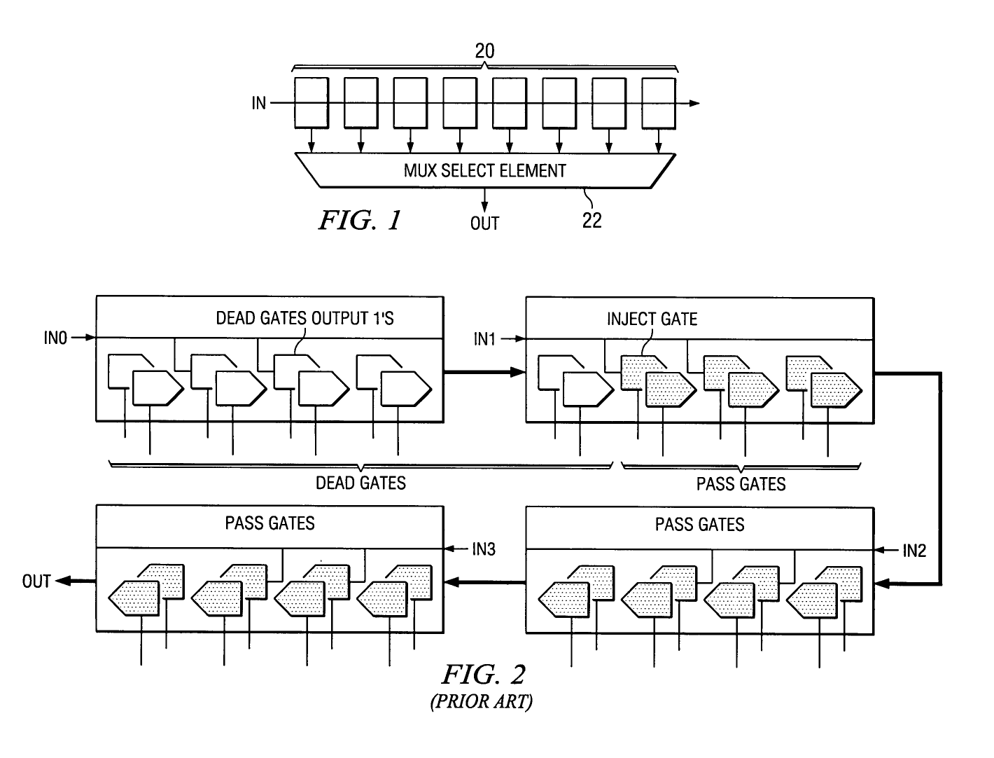

### DETAILED DESCRIPTION OF PREFERRED EMBODIMENTS

A digital delay line can be used in digital phase locked loops (PLL) or digital delay locked loops (DLL). The basic idea is to provide changeable delay to the input clock phase by adjusting the number of delay elements used in the delay line. The design of the delay stage, or basic building block, is crucial in determining the minimum delay amount, or step, as well as ease of implementation.

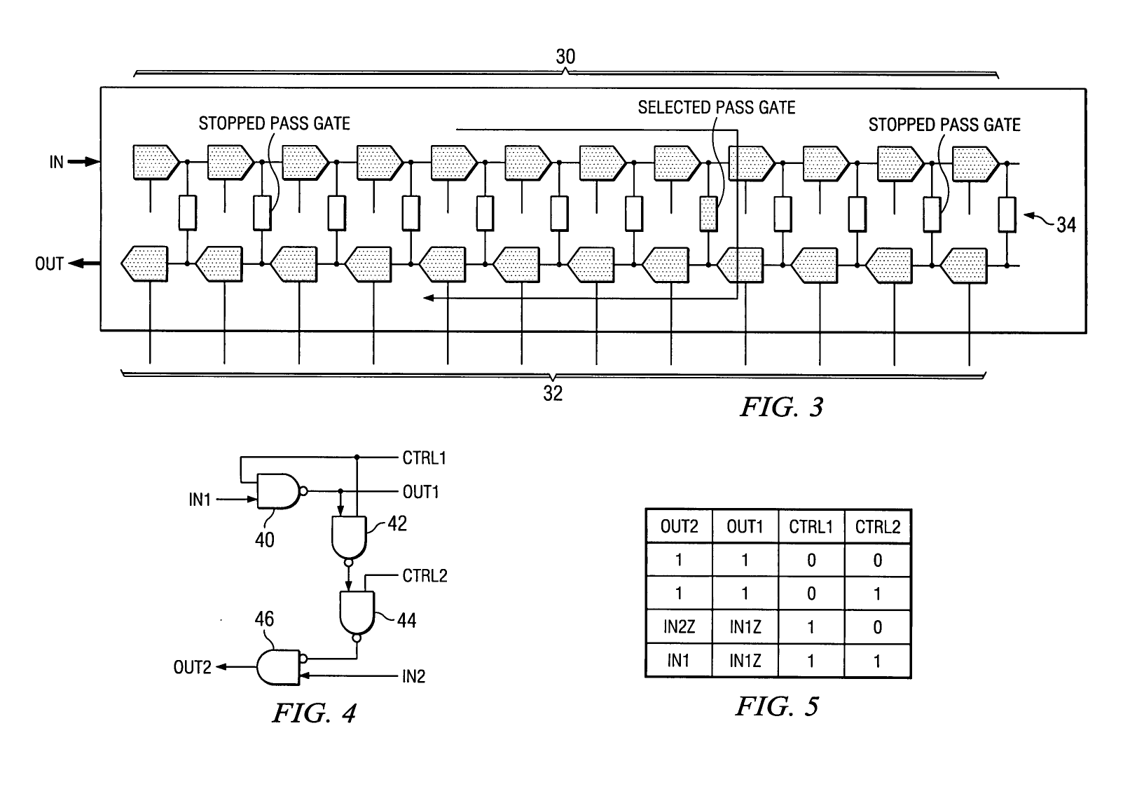

In FIG. 3, a delay stage according to the present invention is shown. This method is called ‘Serial Driving’ method. The device of FIG. 3 includes first delay segments 30; second delay segments 32; and pass gates 34. The idea behind this scheme is similar to what is in FIG. 2. Each delay element is divided into two parts (first delay segment and second delay segment), and are linked with a pass gate. Each pass gate will have three working conditions. In the first working condition the pass gate will output what is on the input of the pass gate. In the second working condition the pass gate will output ‘0’. In the third working condition the pass gate will output ‘1’.

The number of delay elements that make up the delay line is determined by selecting one of the pass gates 34. However, the major difference here is that the input and output ports of this delay line will be placed close to each other. Additional gates are just appended to the existing delay line to make the total delay line longer. It is not constrained by the location of the input clock, as it has only been placed at one place, vs. multiple placements in the scheme shown in FIG. 2.

The success of this scheme lies largely on the design of the delay element. It must have very simple control, and very small overhead while doing the layout, meaning simple logic. A delay element, which is essential for this innovation, is described below.

A delay element, according to the present invention, is shown in FIG. 4. It is composed of four 2-input NAND gates 40, 42, 44, and 46. Two NAND gates 40 and 46 compose the delay that is the minimum delay achievable. NAND gate 40 forms one of the first delay segments 30 in FIG. 3. NAND gate 46 forms one of the second delay segments 32 in FIG. 3. The other two NAND gates 42 and 44 make up the controllable pass gate that accepts two control bits. NAND gates 42 and 44 form one of the pass gates 34 in FIG. 3. Alternatively, two NOR gates can be used instead of NAND gates 42 and 44 to form the pass gate. A truth table for the delay element of FIG. 4 is shown in FIG. 5, where in1z is in1 inverted, and in2z is in2 inverted.

The basic function of a NAND gate is to be shut off by ‘0’ at one input, and acting as an inverter by placing ‘1’ at one input. From the truth table of FIG. 5, the three working conditions are:

1. pass gate, which adds delay to the whole amount, Ctrl1=1, Ctrl2=0.

2. inject gate, which ‘turns’ the signal propagation back to output, Ctrl1=1, Ctrl2=1.

3. dead gate, which outputs ‘1’, Ctrl=0. To enable the inject gate to work properly, the first gate after the inject gate will be a dead gate.

A delay line will be composed of three parts if divided by the functions of the elements. It must have this structure, which coincident with FIG. 3.

When the control bits are listed in a line, the desired sequence is:

CTRL1: . . . 1 1 1 1 1 1 1 1 “1” 0 0 0 0 0 0 0 . . .
CTRL2: . . . 0 0 0 0 0 0 0 0 “1” 1 1 1 1 1 1 1 . . .

The underlined portion shows the dead gates. The quotation marks show the inject gate. It is very obvious CTRL1 can be realized by a shift register. The benefit of using a shift register is to combine logic with the register that is needed to hold bit value. If CTRL1 can be listed as:

CTRL1: . . . b0 b1 b2 b3 b4 b5 b6 b7 b8 b9 b10 . . .
CTRL2 can be:
CTRL2: . . . b1 b2 b3 b4 b5 b6 b7 b8 b9 b10 b11 . . .
The underscore shows the complimentary signal.

When changing the amount of delay elements in the device of FIG. 3, shift left will reduce the number, shift right will increase the number.

The new digital delay element, according to the present invention, is the essential part of a better-designed digital delay line. This kind of delay line has very simple control logic. At the same time, it eliminates errors introduced by routing clocks/input phases to different locations which add an uncertain amount of delay. The additional benefit of this delay element is that stage toggling is shut off after the pass gate. This saves power and reduces negative effects caused by toggling.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore

What is claimed is:

1. A delay stage for a digital delay line comprising:
a first string of delay segments coupled in series;
a second string of delay segments coupled in series;
pass gates coupled between the first string of delay segments and the second string of delay segments, wherein each delay segment in the first string of delay segments has an output coupled to an input of a corresponding one of the pass gates, and a corresponding delay segment in the second string of delay segments has an input coupled to an output of the corresponding one of the pass gates.

2. The device of claim 1 wherein each of the pass gates has three working conditions.

3. The device of claim 1 wherein each of the pass gates has an output node and an input node, wherein a signal on the input node is provided on the output node in a first working condition, a logic zero is provided on the output node in a second working condition, and a logic one is provided on the output node in a third working condition.

4. The device of claim 1 wherein each delay segment in the first string of delay segments is a logic gate.

5. The device of claim 1 wherein each delay segment in the first string of delay segments is a NAND gate.

6. The device of claim 1 wherein each delay segment in the second string of delay segments is a logic gate.

7. The device of claim 1 wherein each delay segment in the second string of delay segments is a NAND gate.

8. The device of claim 1 wherein each of the pass gates comprises:
a first logic gate having a first input coupled to an output of a delay segment in the first string of delay segments and a second input coupled to a first control node;
a second logic gate having a first input coupled to an output of the first logic gate, a second input coupled to a second control node, and an output coupled to an input of a delay segment in the second string of delay segments.

9. The device of claim 8 wherein the first logic gate is a NAND gate.

10. The device of claim 8 wherein the second logic gate is a NAND gate.

11. A delay element for a digital delay line comprising:
a first delay segment having a first input coupled to a first input node and a second input coupled to a first control node;
a first pass gate element having a first input coupled to an output of the first delay segment and a second input coupled to the first control node;
a second pass gate element having a first input coupled to an output of the first pass gate element and a second input coupled to a second control node; and
a second delay segment having a first input coupled to an output of the second pass gate element and a second input coupled to a second input node, wherein the first and second pass gate elements form a pass gate between the first and second delay segments.

12. The device of claim 11 wherein first delay segment is a logic gate.

13. The device of claim 11 wherein the first delay segment is a NAND gate.

14. The device of claim 11 wherein the first pass gate element is a logic gate.

15. The device of claim 11 wherein the first pass gate element is a NAND gate.

16. The device of claim 11 wherein the second pass gate element is a logic gate.

17. The device of claim 11 wherein the second pass gate element is a NAND.

18. The device of claim 11 wherein the second delay segment is a logic gate.

19. The device of claim 11 wherein the second delay segment is a NAND gate.
